(19) United States
(12) Patent Application Publication
(10) Pub. No.: US 2023/0344339 A1
(43) Pub. Date: Oct. 26, 2023

(54) MODULATION POWER SUPPLY DEVICE

(71) Applicant: Fujitsu Limited, Kawasaki-shi (JP)

(72) Inventor: Tatsuya HIROSE, Yokohama (JP)

(73) Assignee: Fujitsu Limited, Kawasaki-shi (JP)

(21) Appl. No.: 18/085,960

(22) Filed: Dec. 21, 2022

(30) Foreign Application Priority Data
Apr. 22, 2022 (JP) 2022-070852

(51) Int. Cl. H02M 3/158; H02M 7/5395

(52) U.S. Cl. CPC H02M 3/158; H02M 7/5395

(57) ABSTRACT

A modulation power supply device, in one aspect, includes a signal source that generates a signal having a predetermined frequency, a frequency converter that converts the signal generated at the signal source to a sampling signal having a frequency higher than the predetermined frequency, a generator that generates a pulse signal by using the sampling signal that has been subjected to frequency conversion by the frequency converter, and a switching power supply that includes a switch operating according to the pulse signal generated by the generator and outputs voltage according to operation of the switch.

### CROSS-REFERENCE TO RELATED APPLICATION

This application is based upon and claims the benefit of priority of the prior Japanese Patent Application No. 2022-070852, filed on Apr. 22, 2022, the entire contents of which are incorporated herein by reference.

### FIELD

The embodiment discussed herein is related to a modulation power supply device.

### BACKGROUND

Switching power supplies are used in general as power supplies for application of voltage to amplifiers of wireless communication devices, for example. A step-down switching power supply (a buck converter) that is currently used widely includes two switches. Turning these switches on and off according to pulse signals inverse of each other enables control of output voltage correspondingly to a pulse duty ratio. In a case where such a switching power supply is used for an amplifier of a wireless communication device, operating switches by means of pulse signals according to an envelope component of a transmission signal changes voltage applied to the amplifier correspondingly to the envelope component and amplifies a high-frequency carrier component by input of the high-frequency carrier component to the amplifier. The amplifier is thereby able to be operated highly efficiently.

Pulse signals to operate switches of a switching power supply are obtained by, for example, pulse width modulation. Specifically, magnitudes of an envelope signal and a sampling signal having any waveform and frequency are compared to each other by a comparator and a pulse signal corresponding to an interval where the envelope signal is larger than the sampling signal is generated, for example. Furthermore, this pulse signal is inverted by, for example, a logical negation circuit, and an inverse pulse signal is thereby generated. These pulse signal and inverse pulse signal are respectively supplied to the two switches of the switching power supply, the two switches thereby operate, and voltage corresponding to the envelope signal is thereby output.
Patent Literature 1: Japanese Laid-open Patent Publication No. 2013-198148
Patent Literature 2: Japanese Laid-open Patent Publication No. 2010-166157

However, there is a problem that a ripple signal that is an unnecessary noise signal is superimposed on output voltage from a modulation power supply device where a switching power supply as described above is used. That is, the output voltage from the modulation power supply over time has a waveform having the waveform of a high frequency ripple signal superimposed on the waveform of the envelope signal. As a result, if the output voltage from the modulation power supply device is applied to an amplifier of a wireless communication device, for example, accurate amplification of the original transmission signal becomes difficult.

Accordingly, a modulation power supply device that has been proposed has plural switching power supplies connected in parallel and each having switches respectively operated by pulse signals having phases different from each other. That is, pulse width modulation of one envelope signal is performed by use of plural sampling signals having phases different from one another and plural pulse signals and inverse pulse signals having time differences are generated. The switching power supplies connected in parallel are driven by these pulse signals and inverse pulse signals, output voltage from the modulation power supply device is thereby smoothed, and the ripple signal is able to be reduced.

However, multiple switching power supplies and circuits that supply pulse signals and inverse pulse signals respectively having different phases from each other to these switching power supplies are needed for sufficient reduction of the ripple signal and there is thus a problem that the cost is thereby increased.

### SUMMARY

According to an aspect of an embodiment, a modulation power supply device, includes a signal source that generates a signal having a predetermined frequency, a frequency conversion unit that converts the signal generated at the signal source, into a sampling signal having a frequency higher than the predetermined frequency, a generation unit that generates a pulse signal by using the sampling signal resulting from frequency conversion by the frequency conversion unit, and a switching power supply that includes a switch operating according to the pulse signal generated by the generation unit and outputs voltage according to operation of the switch.

The object and advantages of the disclosure will be realized and attained by means of the elements and combinations particularly pointed out in the claims.

It is to be understood that both the foregoing general description and the following detailed description are exemplary and explanatory and are not restrictive of the disclosure, as claimed.

### BRIEF DESCRIPTION OF DRAWINGS

FIG. 1 is a diagram of a configuration of a modulation power supply device;

FIG. 2 is a diagram of an example of a configuration of a power splitter;

FIG. 3A is a diagram of examples of a configuration of a phaser;

FIG. 3B is a diagram of examples of a configuration of a phaser;

FIG. 4A is a diagram of examples of a configuration of a level adjustment unit;

FIG. 4B is a diagram of examples of a configuration of a level adjustment unit;

FIG. 5A is a diagram of other examples of the configuration of the level adjustment unit;

FIG. 5B is a diagram of other examples of the configuration of the level adjustment unit;

FIG. 6 is a diagram of yet another example of the configuration of the level adjustment unit;

FIG. 7 is a diagram of a configuration of a sampling signal generation unit;

FIG. 8 is a diagram of a configuration of a step-down modulation power supply unit; and

FIG. 9 is a diagram of a configuration of a control unit.

### DESCRIPTION OF EMBODIMENT

Preferred embodiments of the present disclosure will be explained with reference to accompanying drawings. The present disclosure is not to be limited by this embodiment.

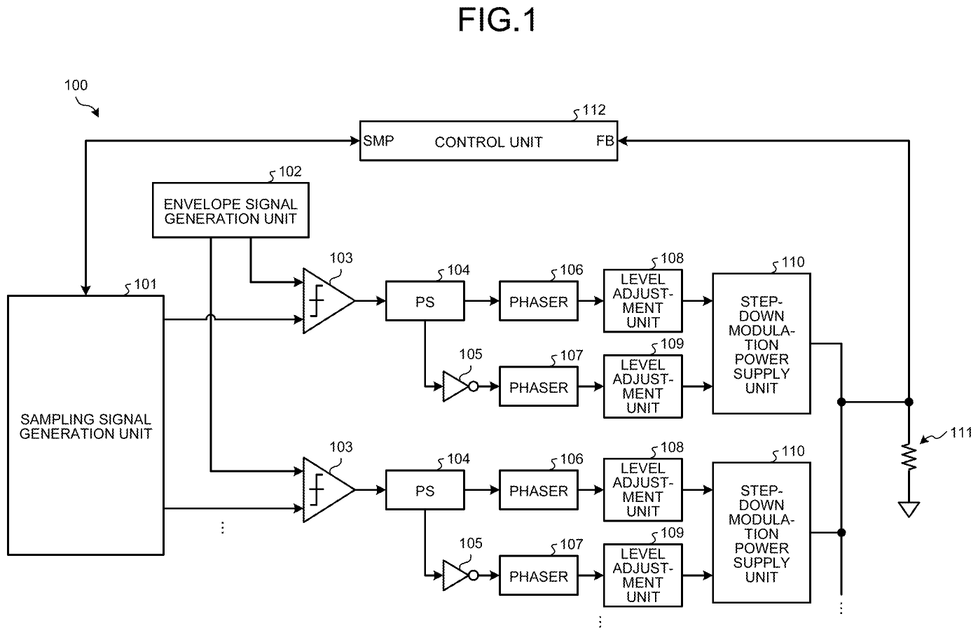

FIG. 1 is a diagram of a configuration of a modulation power supply device 100 according to one embodiment. This modulation power supply device 100 is used as a power supply that applies voltage to an amplifier included in a wireless communication device, for example. The modulation power supply device 100 illustrated in FIG. 1 has a sampling signal generation unit 101, an envelope signal generation unit 102, a comparator 103, a power splitter (abbreviated as “PS” in FIG. 1) 104, a logical negation circuit 105, phasers 106 and 107, level adjustment units 108 and 109, a step-down modulation power supply unit 110, a load 111, and a control unit 112.

The sampling signal generation unit 101 generates a sampling signal to be used in pulse width modulation. That is, the sampling signal generation unit 101 generates a sampling signal to be used in generation of a pulse signal according to an envelope signal. The sampling signal generation unit 101 generates, from a signal generated by a signal source and having a predetermined frequency, plural sampling signals having a frequency that is twice the predetermined frequency or higher, the plural sampling signals having phases different from each other. A specific configuration of the sampling signal generation unit 101 will be described in detail later.

The envelope signal generation unit 102 generates an envelope signal by extracting an envelope component from a transmission signal, for example. That is, the envelope signal generation unit 102 generates an envelope signal having a waveform corresponding to transmission data.

The comparator 103 makes a comparison of magnitudes of the sampling signal and the envelope signal and outputs a pulse signal according to a result of the comparison. Specifically, for example, the comparator 103 outputs a pulse signal by outputting high voltage in an interval where the envelope signal is larger than the sampling signal and outputting low voltage in any other interval. Because phases of sampling signals respectively input to a plurality of the comparators 103 are different from one another, the comparators 103 respectively output different pulse signals according to the phases of the sampling signals. Furthermore, because the frequency of a sampling signal is higher than the predetermined frequency of the signal generated by the signal source, a pulse signal output by the comparator 103 reflects the envelope signal at a higher resolution than that in a case where the signal from the signal source is directly used as a sampling signal.

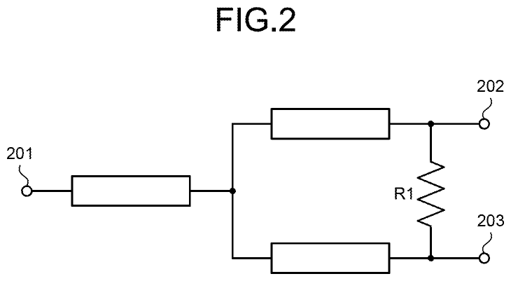

The power splitter 104 splits a pulse signal output from the comparator 103 and outputs the split pulse signals to the phaser 106 and the logical negation circuit 105. Specifically, the power splitter 104 may have a configuration illustrated in FIG. 2, for example. As illustrated in FIG. 2, the power splitter 104 has two output terminals 202 and 203 for one input terminal 201 and is formed of: a distributed constant circuit or wiring; and a resistance element R1. The power splitter 104 is theoretically compatible with frequency of up to infinite frequency, and impedance and electrical length of the distributed constant circuit or wiring are set according to a frequency to be used. Furthermore, a resistance value is set for the resistance element R1 in consideration of quantity of attenuation for attenuation of differently phased signals between the output terminals 202 and 203.

The logical negation circuit 105 inverts a pulse signal output from the power splitter 104 and outputs an inverse pulse signal obtained as a result, to the phaser 107.

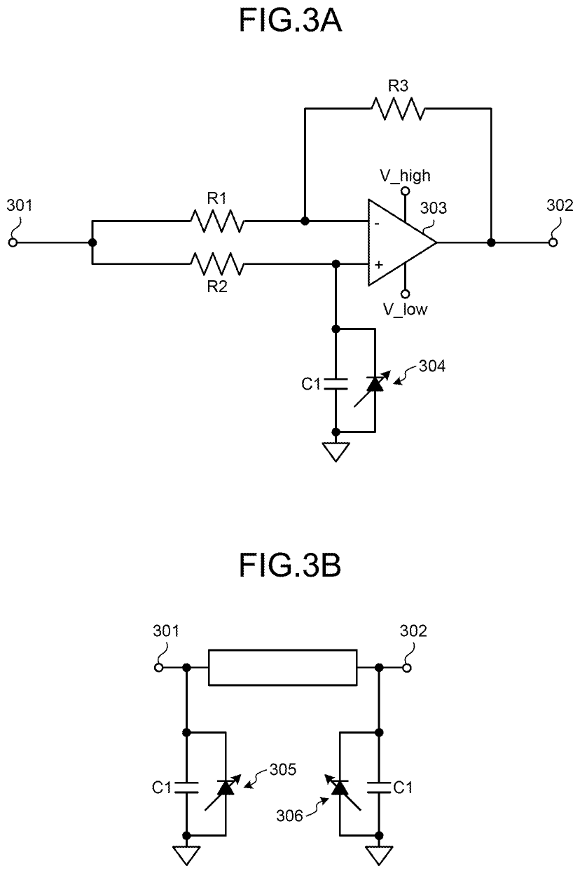

The phasers 106 and 107 respectively adjust phases of a pulse signal and an inverse pulse signal to make their skews match each other. Specifically, the phasers 106 and 107 may be configured as illustrated in FIG. 3A or FIG. 3B, for example.

In the configuration illustrated in FIG. 3A, a pulse signal or an inverse pulse signal is input from an input terminal 301, and is output from an output terminal 302 after its phase has been adjusted. The pulse signal or inverse pulse signal input is distributed to resistance elements R1 and R2, and the signal distributed to the resistance element R1 is input to one of terminals of an operational amplifier 303 and input to a feedback resistance element R3 of the operational amplifier 303. Furthermore, the signal distributed to the resistance element R2 is input to the other terminal of the operational amplifier 303 and input to a circuit having a capacitance element C1 and a variable capacitance diode 304 connected in parallel. V_high is a positive supply to the operational amplifier 303. V_low is a negative supply to the operational amplifier 303. Setting the ratio between resistance values of the resistance element R1 and the feedback resistance element R3 to 1:1 and adjusting the resistance value of the resistance element R2 and the capacitance value of the combined circuit formed of the capacitance element C1 and the variable capacitance diode 304 enable output of the input signal input from the input terminal 301, from the output terminal 302, with the phase of the input signal having been changed.

In the configuration illustrated in FIG. 3B also, a pulse signal or an inverse pulse signal is input from an input terminal 301, and is output from an output terminal 302 after its phase has been adjusted. The input terminal 301 and the output terminal 302 are connected by a distributed constant transmission line, and a combined circuit including a capacitance element C1 and variable capacitance diode 305 and a combined circuit including a capacitance element C1 and a variable capacitance diode 306 are respectively connected to two ends of the distributed constant transmission line. In this configuration, adjusting the capacitance values of the combined circuits including the capacitance elements C1 and the variable capacitance diodes 305 and 306 enables output of the input signal input from the input terminal 301, from the output terminal 302, with the phase of the input signal having been changed.

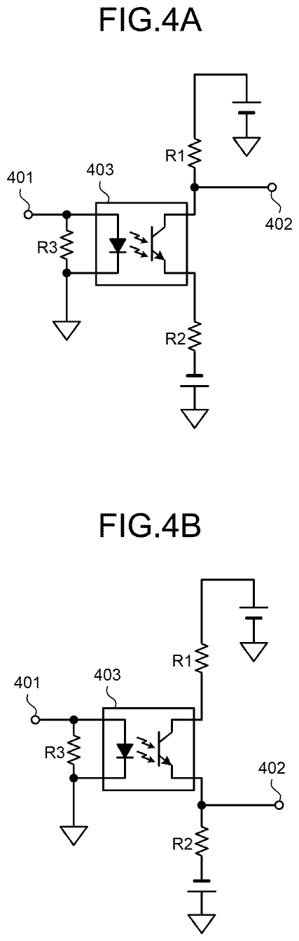

The level adjustment units 108 and 109 respectively make the direct current voltage levels of a pulse signal and an inverse pulse signal equal to, or isolate the direct current voltage levels from, the input voltage levels at switches included in the step-down modulation power supply unit 110 downstream from the level adjustment units 108 and 109. Specifically, the level adjustment units 108 and 109 may be configured as illustrated in FIG. 4A or FIG. 4B, for example, by use of a photocoupler.

As illustrated in FIG. 4A and FIG. 4B, the level adjustment units 108 and 109 adjust the level of a pulse signal or an inverse pulse signal input from an input terminal 401 and output the adjusted signal from an output terminal 402. A resistance element R3 is connected to an input end of a photocoupler 403 to prevent generation of floating voltage. An output end of the photocoupler 403 is generally formed of a bipolar transistor, and a resistance element R1 and a power supply, and a resistance element R2 and a power supply are thus respectively connected to a collector terminal and an emitter terminal of the bipolar transistor. In FIG. 4A, the output terminal 402 is provided near the collector terminal and in FIG. 4B, the output terminal 402 is provided near the emitter terminal. Which one of the configurations in FIG. 4A and FIG. 4B is to be adopted for the level adjustment units 108 and 109 may be selected depending on whether: the level adjustment units 108 and 109 are to have gains; or their gains are to be set at 1 and the level adjustment units 108 and 109 are to operate as buffers.

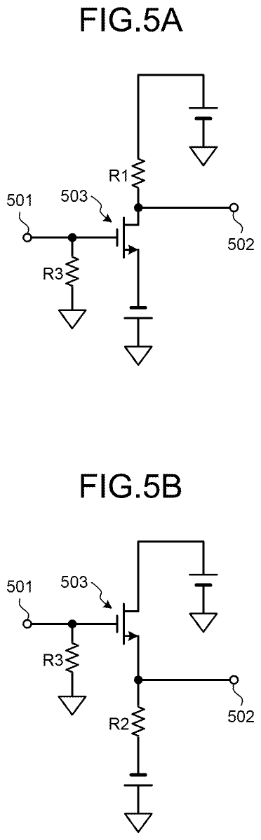

The level adjustment units 108 and 109 may each be configured as illustrated in FIG. 5A or FIG. 5B, for example, by use of a field effect transistor or a metal oxide semiconductor (MOS) transistor.

As illustrated in FIG. 5A and FIG. 5B, the level adjustment units 108 and 109 adjust the level of a pulse signal or an inverse pulse signal input from an input terminal 501 and output the adjusted signal from an output terminal 502. A resistance element R3 is connected to a gate terminal of a transistor 503 to prevent generation of floating voltage. In FIG. 5A, a resistance element R1 and a power supply are connected to a drain terminal of the transistor 503 and a power supply is connected to a source terminal of the transistor 503. The output terminal 502 is provided near the drain terminal. In FIG. 5B, a power supply is connected to a drain terminal of a transistor 503 and a resistance element R2 and a power supply are connected to a source terminal of the transistor 503. The output terminal 502 is provided near the source terminal. Which one of the configurations in FIG. 5A and FIG. 5B is to be adopted for the level adjustment units 108 and 109 may be selected depending on whether: the level adjustment units 108 and 109 are to have gains; or their gains are to be set at 1 and the level adjustment units 108 and 109 are to operate as buffers.

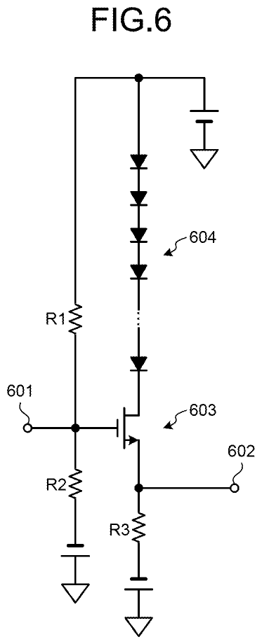

The level adjustment units 108 and 109 configured by use of field effect transistors may be configured as illustrated in FIG. 6.

As illustrated in FIG. 6, the level adjustment units 108 and 109 adjust the level of a pulse signal or an inverse pulse signal input from an input terminal 601, and output the adjusted signal from an output terminal 602. In this configuration, a circuit having diodes 604 connected in series is connected to a drain terminal of a transistor 603 and the drain voltage level is shifted downward. Furthermore, by connection of a resistance element R3 and a power supply to a source terminal of the transistor 603, the direct current voltage level of the source terminal is shifted downward. This configuration enables increase in the number of variables for adjustment of the direct current voltage levels of the input terminal 601 and output terminal 602.

The step-down modulation power supply unit 110 is a switching power supply that supplies voltage resulting from drop of the power supply voltage and outputs voltage modulated according to an envelope signal. That is, the step-down modulation power supply unit 110 includes switches that are turned on and off according to a pulse signal and an inverse pulse signal, and the step-down modulation power supply unit 110 applies modulated voltage to the load 111 by operating these switches oppositely to each other. Because pulse signals and inverse pulse signals that have been subjected to pulse width modulation on the basis of sampling signals having phases different from one another are respectively input to a plurality of the step-down modulation power supply units 110, ripple signals in the voltage applied to the load 111 by these step-down modulation power supply units 110 are reduced. A specific configuration of the step-down modulation power supply unit 110 will be described in detail later.

The load 111 operates by application of output voltage from the plural step-down modulation power supply units 110 to the load 111. The load 111 is, for example, an amplifier of a wireless communication device, and amplifies a transmission signal corresponding to an envelope signal, highly efficiently.

The control unit 112 controls phases of plural sampling signals generated by the sampling signal generation unit 101. That is, on the basis of a sampling signal input to a terminal SMP and a feedback signal that is equal to voltage applied to the load 111 and that is fed back to a terminal FB, the control unit 112 appropriately controls phases of plural sampling signals to reduce ripple signals included in the voltage applied. A specific configuration of the control unit 112 will be described in detail later.

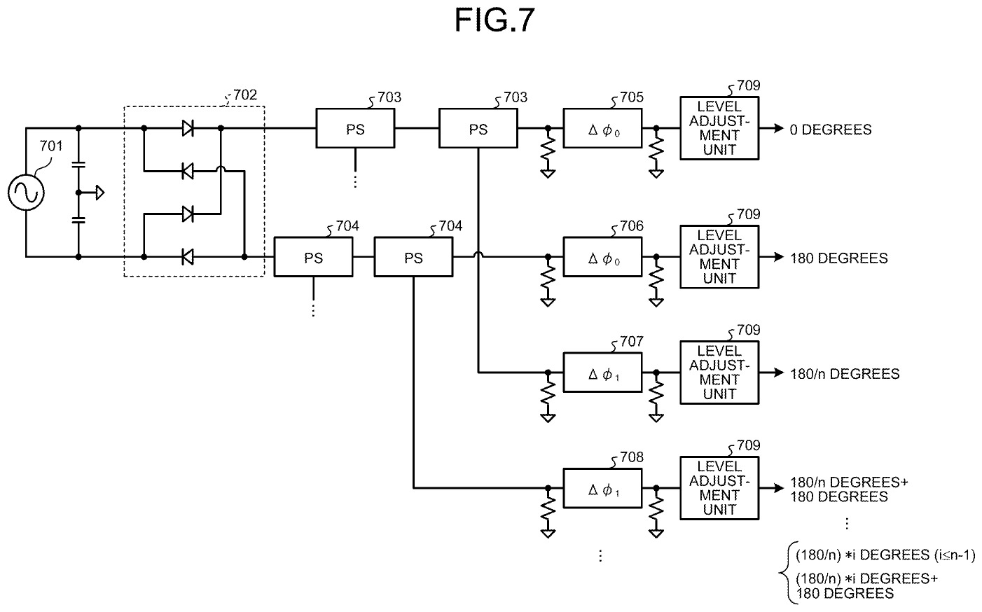

FIG. 7 is a diagram of a configuration of the sampling signal generation unit 101. As illustrated in FIG. 7, the sampling signal generation unit 101 has a signal source 701, a frequency conversion circuit 702, power splitters 703 and 704, phasers 705 to 708, and level adjustment units 709. This sampling signal generation unit 101 generates 2n (n is an integer of 1 or larger) sampling signals having phases different from one another.

The signal source 701 is a signal source that generates a signal of a predetermined frequency f₀ and is configured by use of, for example, a bipolar alternating current power supply. Two ends of the signal source 701 each have one of terminals of a capacitance element connected thereto, and the other terminals of these capacitance elements are grounded.

The frequency conversion circuit 702 includes, for example, a full wave rectifier formed by use of diodes, and converts the frequency f₀ of the signal generated by the signal source 701 to, for example, a frequency 2f₀ that is twice the frequency f₀. That is, the frequency conversion circuit 702 outputs signals having the frequency 2f₀ by rectifying the waveform of a signal output to both ends of the signal source 701, the waveform fluctuating negatively and positively at the frequency f₀, into a waveform resulting from foldback of a negative portion of the waveform in a positive direction and a waveform resulting from foldback of a positive portion of the waveform in a negative direction. Therefore, the frequency conversion circuit 702 outputs a positive signal and a negative signal inverse of each other and having a frequency that is twice the frequency of the signal generated at the signal source 701. In a case where the frequency conversion circuit 702 is formed by use of diodes, the amplitude of the signal generated by the signal source 701 is preferably made equal to or larger than a voltage that turns the diodes on. Furthermore, the frequency conversion circuit 702 may output a signal having a frequency equal to or higher than the frequency that is twice the frequency of the signal generated at the signal source 701.

The power splitter 703 splits any one of the positive signal and negative signal output from the frequency conversion circuit 702 and outputs the split signal to a phaser (for example, the phaser 707) downstream from the power splitter 703, the phaser having a phase quantity different from that of the phaser 705. The power splitter 704 splits the other one of the positive signal and negative signal output from the frequency conversion circuit 702 and outputs the split signal to a phaser (for example, the phaser 708) downstream from the power splitter 704, the phaser having a phase quantity different from that of the phaser 706. The power splitters 704 and 704 may be configured similarly to the power splitter 104 (FIG. 2).

The phasers 705 to 708 each adjust the phase of the positive signal or negative signal according to control by the control unit 112 to make phases of sampling signals output from the phasers 705 to 708 different from one another.

Specifically, the sampling signal generation unit 101 includes n pairs of phasers including the phasers 705 to 708, and each pair of phasers respectively adjust phases of a positive signal and a negative signal according control by the control unit 112. Because the positive signal and the negative signal are signals inverse of each other, each pair of phasers respectively output sampling signals having phases different from each other by 180 degrees.

For example, the pair of phasers 705 and 706 have a phase difference Δϕ₀. The pair of phasers 705 and 706 adjust the phases of the positive signal and the negative signal and thereby output sampling signals having phases of 0 degrees and 180 degrees. Furthermore, for example, the pair of phasers 707 and 708 have a phase difference Δϕ₁. The pair of phasers 707 and 708 adjust the phases of the positive signal and the negative signal and thereby output sampling signals having phases of 180/n degrees and (180/n+180) degrees. That is, a pair i (i is an integer from 0 to (n−1)) of phasers of the n pairs of phasers output sampling signals having phases of (180/n×i) degrees and (180/n×i+180) degrees. The n pairs of phasers including the phasers 705 to 708 may each be configured similarly to the phasers 106 and 107 (FIGS. 3A and 3B).

The level adjustment units 709 make the direct current voltage levels of the sampling signals having phases different from one another and the frequency 2f₀, equal to the input voltage levels of the comparators 103 downstream from the level adjustment units 709. The level adjustment units 709 may be configured similarly to the level adjustment units 108 and 109 (FIG. 4A to FIG. 6).

As described above, the sampling signal generation unit 101 converts a signal generated at the signal source 701 to a positive signal and a negative signal having a frequency that is twice the frequency of the signal or higher, by means of the frequency conversion circuit 702, and generates 2n sampling signals having phases different from one another by means of n pairs of phasers from the positive signal and negative signal. The 2n sampling signals are respectively input to the comparators 103 and a comparison between the magnitudes of the sampling signals and the magnitude of an envelope signal is made, and on the basis of a result of the comparison, pulse signals to operate the switches of the step-down modulation power supply unit 110 are output.

Because the phases of the sampling signals input to the comparators 103 are different from one another, the plural comparators 103 perform pulse width modulation of the same envelope signal by respectively using the sampling signals having the phases different from one another. As a result, time differences are generated in operation of the switches of the plural step-down modulation power supply units 110 and ripple signals in voltage applied by the plural step-down modulation power supply units 110 to the load 111 are able to be reduced.

Furthermore, because the frequencies of sampling signals input to the comparators 103 are higher than the frequency of the signal generated at the signal source 701, the resolution in the pulse width modulation of the envelope signal is increased and the pulse signals reflect the envelope signal highly accurately. As a result, even in a case where voltage is applied to the load 111 by a comparatively small number of step-down modulation power supply units 110, ripple signals are able to be reduced and increase in cost due to increase in the number of circuits is able to be minimized.

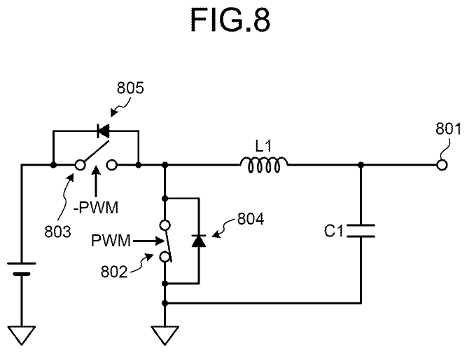

FIG. 8 is a diagram of a configuration of the step-down modulation power supply unit 110. As illustrated in FIG. 8, the step-down modulation power supply unit 110 outputs voltage obtained by drop of the power supply voltage, from an output terminal 801. The step-down modulation power supply unit 110 has two switches 802 and 803 that respectively operate according to a pulse signal PWM and an inverse pulse signal (−PWM) output from the level adjustment units 108 and 109. That is, when one of the switches 802 and 803 is on, the other one of the switches 802 and 803 is off, and when the one of the switches 802 and 803 is off, the other one is on. The pulse signal PWM and inverse pulse signal (−PWM) are obtained by pulse width modulation of an envelope signal through use of sampling signals, and operation of the switches 802 and 803 thus reflects the envelope signal and output voltage corresponding to the envelope signal is able to be obtained.

In case the switches 802 and 803 are both turned off and the potential difference between the two ends of each of the switches 802 and 803 becomes very high, protection diodes 804 and 805 are respectively connected between the terminals of the switch 802 and between the terminals of the switch 803.

As a result of the switches 802 and 803 operating according to a pulse signal and an inverse pulse signal, electric current according to the envelope signal is supplied by an induction element L1 and this electric current is temporarily accumulated by a capacitance element C1. Output voltage is applied to the load 111 from the output terminal 801 by discharge of the electric current accumulated by the capacitance element C1.

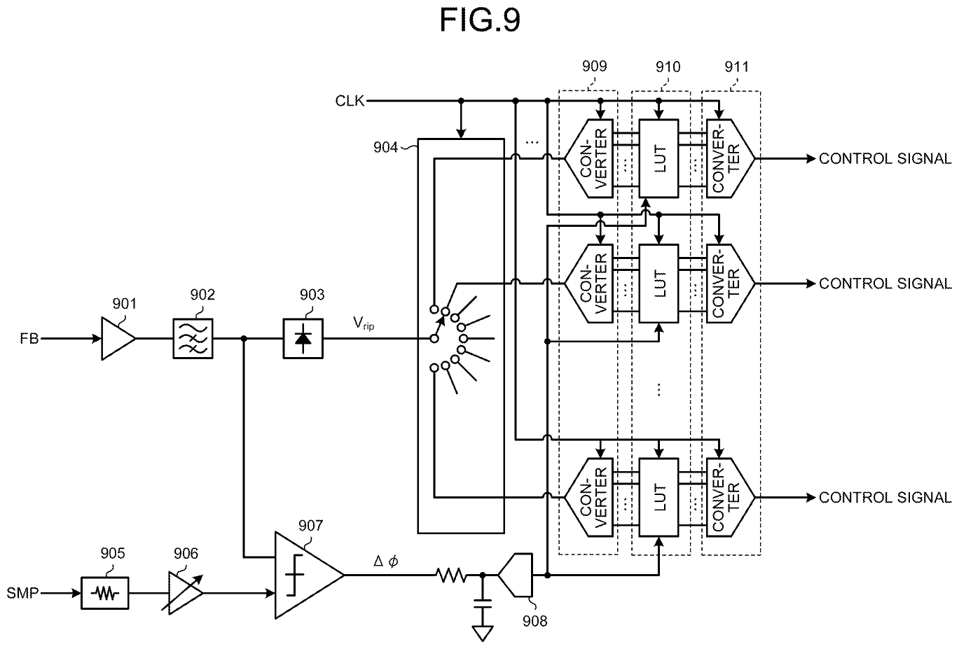

FIG. 9 is a diagram of a configuration of the control unit 112. As illustrated in FIG. 9, the control unit 112 has: an amplifier 901, a filter 902, a wave detector 903, and a selector 904 that are connected to the terminal FB; and an attenuator 905 and a variable gain amplifier 906 that are connected to the terminal SMP. Furthermore, the control unit 112 has a comparator 907, analog/digital (A/D) converters 908 and 909, lookup tables 910 (each abbreviated as “LUT” in FIG. 9), and digital/analog (D/A) converters 911.

Voltage applied to the load 111 is fed back to the terminal FB. The voltage applied to the load 111 may be divided to be reduced in absolute value and a feedback signal obtained as a result may be fed back to the terminal FB. The feedback signal is amplified by the amplifier 901, and a frequency component corresponding to a ripple signal is extracted from the feedback signal by the filter 902. The ripple signal extracted is input to the wave detector 903 and converted to a direct current signal corresponding to the maximum voltage. Voltage Vᵣᵢₚ (hereinafter, referred to as “ripple voltage”) of the signal converted into direct current is input to an input terminal of the selector 904, and is output from an output terminal connected to the input terminal, to any one of the A/D converters 909.

The number of output terminals provided in the selector 904 is the same as the number of the plural phasers including the phasers 705 to 708 in the sampling signal generation unit 101, and these output terminals respectively have connection to the A/D converters 909, lookup tables 910, and D/A converters 911. Connections between the input terminal and the output terminals of the selector 904 are able to be changed according to a predetermined clock signal CLK. Therefore, the ripple voltage Vᵣᵢₚ is output to the plural A/D converters 909 in turn. The ripple voltage Vᵣᵢₚ is A/D converted at each of the A/D converters 909 and input to the lookup tables 910 corresponding to the A/D converters 909.

A sampling signal having a frequency that has been converted by the frequency conversion circuit 702 of the sampling signal generation unit 101 is input to the terminal SMP. The sampling signal is attenuated by the attenuator 905 for reduction of reflection, and is amplified by the variable gain amplifier 906 to a level where phase comparison is possible. The sampling signal is then input as a reference signal to one of terminals of the comparator 907. The ripple signal extracted by the filter 902 is input to the other terminal of the comparator 907 and a phase difference Δϕ between the reference signal and the ripple signal is output by comparison between the reference signal and the ripple signal.

The phase difference Δϕ passes through a low frequency signal filter formed of a resistance element and a capacitance element and is converted to a direct current signal. In a case where the phase of the ripple signal is ahead of the sampling signal that is the reference signal, the direct current signal value of the phase difference Δϕ is larger than 0; in a case where the phase of the sampling signal and the phase of the ripple signal match each other, the direct current signal value of the phase difference Δϕ becomes 0; and in a case where the phase of the ripple signal is more delayed than that of the sampling signal, the direct current signal value of the phase difference Δϕ becomes less than 0. The direct current signal value is A/D converted at the A/D converter 908 and is then input to the lookup tables 910.

The lookup tables 910 store values of bias voltage set for the phasers correspondingly to the ripple voltage Vᵣᵢₚ. That is, the lookup tables 910 store values of the bias voltage for reducing the ripple signals in association with values of the ripple voltage Vᵣᵢₚ. The larger that ripple voltage Vᵣᵢₚ, the smaller the bias voltage stored by the lookup tables 910, in the case where the direct current signal value of the phase difference Δϕ is larger than 0. In contrast, the larger that ripple voltage Vᵣᵢₚ, the larger the bias voltage stored by the lookup tables 910, in the case where the direct current signal value of the phase difference Δϕ is smaller than 0.

In response to input of the ripple voltage Vᵣᵢₚ and the direct current signal value of the phase difference Δϕ to a lookup table 910, a bias voltage corresponding to the ripple voltage Vᵣᵢₚ and direct current signal value of the phase difference Δϕ is output to a D/A converter 911. The bias voltage is then D/A converted by the D/A converter 911, and an analog control signal converted is output to corresponding phasers (for example, the phasers 705 to 708) of the sampling signal generation unit 101. Furthermore, a control signal obtained from the bias voltage stored in the lookup table 910 is similarly output to the corresponding phasers 106 and 107. Phase quantities at the phasers of the sampling signal generation unit 101 and the phasers 106 and 107 are thereby able to be controlled appropriately and the ripple signals are thereby able to be reduced.

As described above, according to this embodiment, a sampling signal having a frequency higher than that of a signal from a signal source is generated by conversion of the frequency of the signal generated at the signal source, an envelope signal is subjected to pulse width modulation by use of plural sampling signals having different phases, and switches of plural switching power supplies are operated by plural pulse signals obtained as a result. Therefore, time differences are generated in operation of the switches of the switching power supplies, and ripple signals in voltage applied from the plural switching power supplies are able to be reduced. Furthermore, because the frequency of the sampling signals is high, the ripple signals are able to be reduced even in a case where voltage is applied from a comparatively small number of switching power supplies, and increase in cost dues to increase in the number of circuits is able to be minimized.

A modulation power supply device disclosed by the present application, in one aspect, achieves an effect of enabling: minimization of increase in cost; and reduction of a ripple signal.

All examples and conditional language recited herein are intended for pedagogical purposes of aiding the reader in understanding the disclosure and the concepts contributed by the inventor to further the art, and are not to be construed as limitations to such specifically recited examples and conditions, nor does the organization of such examples in the specification relate to a showing of the superiority and inferiority of the disclosure. Although the embodiment of the present disclosure has been described in detail, it should be understood that the various changes, substitutions, and alterations could be made hereto without departing from the spirit and scope of the disclosure.

What is claimed is:

1. A modulation power supply device, comprising:
a signal source that generates a signal having a predetermined frequency;
a frequency converter that converts the signal generated at the signal source, into a sampling signal having a frequency higher than the predetermined frequency;
a generator that generates a pulse signal by using the sampling signal resulting from frequency conversion by the frequency converter; and
a switching power supply that includes a switch operating according to the pulse signal generated by the generator and outputs voltage according to operation of the switch.

2. The modulation power supply device according to claim 1, wherein the frequency converter includes a diode connected to both ends of the signal source, and generates the sampling signal, by converting frequency of the signal generated at the signal source, through separation of a waveform of the signal in a positive direction and a negative direction.

3. The modulation power supply device according to claim 1, further including:
a phaser that adjusts a phase of the sampling signal; and
a level adjustment circuit that adjusts a level of the sampling signal that has been subjected to phase adjustment by the phaser, wherein
the generator generates the pulse signal by using the sampling signal that has been subjected to level adjustment by the level adjustment circuit.

4. The modulation power supply device according to claim 1, wherein the generator includes a comparator that includes a first input terminal where the sampling signal is input, and a second input terminal where another signal is input, and that generates the pulse signal by comparing the sampling signal input to the first input terminal and the other signal input to the second input terminal to each other.

5. The modulation power supply device according to claim 4, wherein the other signal input to the second input terminal is an envelope signal corresponding to transmission data.

6. The modulation power supply device according to claim 1, further including:
an inverter that generates an inverse pulse signal by inverting the pulse signal generated by the generator, wherein
the switching power supply:
includes a first switch that operates according to the pulse signal and a second switch that operates according to the inverse pulse signal; and
outputs voltage according to operation of the first switch and the second switch.
